(19) United States
(12) Patent Application Publication
(10) Pub. No.: US 2004/0263220 A1
(43) Pub. Date: Dec. 30, 2004

(54) Voltage-controlled switch control device

(75) Inventors: Marc Sabut, Eybens (FR); Francois Van Zanten, Meylan (FR); Jean-Luc Moro, Grenoble (FR)

Correspondence Address: Bryan A. Santarelli, GRAYBEAL JACKSON HALEY LLP, Suite 350, 155 - 108th Avenue NE, Bellevue, WA, 98004-5973, US

(73) Assignee: STMicroelectronics S.A.

(21) Appl. No.: 10/877,747

(22) Filed: Jun. 25, 2004

(30) Foreign Application Priority Data
Jun. 27, 2003 (FR) 03/50271

(51) Int. Cl. H03B 1/00

(52) U.S. Cl. 327/112

(57) ABSTRACT

A device for controlling a voltage-controlled switch from a digital signal, comprising: a first means for providing the digital signal to the output terminal of the switch; a second means for biasing the switch control terminal to a level greater than the threshold voltage of the switch and smaller than the sum of said threshold voltage and of the maximum voltage of the digital signal; and a third means for adding or subtracting to said level said maximum voltage of the digital signal respectively at the rising and falling edges of the logic inverse of the digital signal.

### PRIORITY CLAIM

This application claims priority from French patent application No. 03/50271, filed Jun. 27, 2003, which is incorporated herein by reference.

### BACKGROUND OF THE INVENTION

1. Field of the Invention

The present invention relates generally to the control of a voltage-controlled switch, in particular in a voltage step-up device.

2. Discussion of the Related Art

Some integrated circuits comprise both digital blocks which process the information in the form of digital signals, and analog blocks which process the information in the form of analog signals. The digital blocks may be formed of small-size MOS transistors, powered under a relatively small voltage Vdd, and having a small threshold voltage (of about 0.3 to 0.4 volt). The analog blocks, however, are formed of larger MOS transistors, powered under a voltage Vcc greater than voltage Vdd and having a relatively high threshold voltage (on the order of 1 volt) with respect to transistors powered under voltage Vdd. Hereafter, transistors with a small threshold voltage used to form the digital blocks are called “digital transistors”, and transistors with a strong threshold voltage used to form the analog blocks are called “analog transistors”. So-called voltage step-up devices formed of digital and analog transistors are provided to raise from Vdd to Vcc the voltage of the signals generated by the digital blocks to enable the digital blocks to control analog blocks.

FIG. 1 schematically shows a conventional voltage step-up device, such as used in integrated circuits sold by ST Microelectronics Company under reference STI 5514. Two substantially identical N-channel analog MOS transistors 2 and 4 have their sources connected to a ground voltage GND, and two identical P-channel analog MOS transistors 6 and 8 have their sources connected to a voltage Vcc. The drains of transistors 6 and 8 are respectively connected to the drains of transistors 2 and 4. The gate of transistor 6 is connected to the drain of transistor 8. The gate of transistor 8 is connected to the drain of transistor 6; which forms output terminal OUT of the voltage step-up device towards an analog block not shown. As an alternative, an inverted output is sampled from the drain of transistor 8. The gates of transistors 2 and 4 are respectively connected to the output of two inverters 10 and 12 formed of digital transistors and arranged to be controlled in phase opposition from an input terminal IN and its logic complement NIN. The inverters, formed of digital transistors and supplied between the ground and a digital supply voltage Vdd, are controllable to bring the gates of transistors 2 or 4 to ground or to voltage Vdd.

The above voltage step-up device has several disadvantages. Indeed, if supply voltage Vdd is smaller than threshold voltage Vt of transistors 2 and 4, maximum voltage Vdd at the output of inverters 10 and 12 does not enable turning on one of transistors 2 and 4 and the device does not operate.

If supply voltage Vdd is only slightly greater than threshold voltage Vt, inverters 10 and 12 turn on one of transistors 2 and 4 with a high resistance Ron, which limits the device speed and thereby its operating frequency.

Further, since an increase or a reduction in voltage Vdd respectively causes a reduction or an increase in the device speed, incidental variations of voltage Vdd, for example, introduced by noise on the digital side, translate as an unwanted phase modulation of output terminal OUT of the device.

Another disadvantage appears upon transition between an initial state, in which transistors 2 and 8 are off and transistors 4 and 6 are conductive, and a complementary state. Transistor 2, directly controlled, is rapidly turned on. However, transistor 6 is turned off only when the gate of transistor 6 is at a high voltage, after transistor 8 has been turned on by the lowering of the voltage level of the gate of transistor 8, through transistor 2. Transistors 2 and 6 are thus simultaneously on for a time period which is all the longer as resistance Ron of transistor 2 is high. During this time period, the device consumes a non-settable current depending on resistance Ron of transistor 2, that is, on difference Vt−Vdd.

A similar current consumption also occurs due to a simultaneous turning-on of transistors 4 and 8 upon reverse transition of the device.

The above disadvantages are all the more disturbing as voltage Vcc is high with respect to voltage Vdd. Indeed, the higher voltage Vcc, the higher threshold voltage Vt of transistors 6 and 8 and the doser Vt gets to voltage Vdd. Technological developments further tend to decrease voltage Vdd and reduce the existing interval between voltages Vdd and Vt.

### SUMMARY OF THE INVENTION

An embodiment of the present invention provides a voltage step-up device, the operating speed of which is not reduced, even if there is but a small difference between the digital transistor supply voltage and the analog transistor threshold voltage.

This embodiment also aims at such a device in which incidental variations of the digital transistor supply voltage do not translate as a phase modulation of the device's output terminal.

Another embodiment of the present invention provides a voltage step-up device having a reduced power consumption.

This embodiment also aims at an integrated circuit comprising a digital block capable of providing a control signal to an analog block via such a voltage step-up device.

Another embodiment of the present invention provides a specific control device, formed of digital transistors, enabling turning on with a small resistance Ron an analog transistor, even if there exists but a small difference between the digital transistor supply voltage and the threshold voltage of the analog transistor.

More specifically, this embodiment provides a device for controlling a voltage-controlled switch from a digital signal, comprising: a first means for providing the digital signal to the output terminal of the switch; a second means for biasing the switch control terminal to a level greater than the threshold voltage of the switch and smaller than the sum of said threshold voltage and of the maximum voltage of the digital signal; and a third means for adding or subtracting to said level said maximum voltage of the digital signal respectively at the rising and falling edges of the logic inverse of the digital signal.

According to an embodiment of the present invention, the second means comprises a first resistor arranged between the switch control terminal and a voltage source; and the third means comprises a first capacitor having a first terminal connected to the control terminal of the switch and having its second terminal receiving the digital signal.

This embodiment also provides a voltage step-up device comprising: a first switch having its voltage controlled by such a control device, the input terminal of the first switch forming the output terminal of the voltage step-up device; a second switch identical to the first switch, having its output terminal connected to the second terminal of the capacitor and its control terminal connected to the output of the first means via a second capacitor and connected to the voltage source via a second resistor, and a fourth means capable of bringing the output terminal of the device to a predetermined high voltage, greater than said maximum voltage of the digital signal, when the first switch is non-conductive.

According to an embodiment of the present invention, the fourth means comprises: a third voltage-controlled switch having its control and output terminals respectively connected to the input terminals of the second and first switches; a high voltage source maintaining the input terminal of the third switch at the high voltage; and a fourth switch identical to the third switch, having its input and output terminals respectively connected to the high voltage source and to the input terminal of the second switch, the control terminal of the fourth switch being connected to the control terminal of the third switch via a third resistor and to the high voltage source via a third capacitor.

According to an embodiment of the present invention, the fourth means comprises: a third voltage-controlled switch having its control and output terminals respectively connected to the input terminals of the second and first capacitors; a high voltage source maintaining the input terminal of the third switch at the high voltage; and a fourth switch identical to the third switch, having its input, control, and output terminals respectively connected to the high voltage source and to the input terminals of the first and second switches.

Another embodiment of the invention provides an integrated circuit comprising a digital block capable of providing a control signal to an analog block via such a voltage step-up device, in which the maximum voltage of the digital signal is equal to the digital block supply voltage and in which the high voltage is equal to the supply voltage of the analog block.

According to an embodiment of the present invention, the first and third switches respectively are N- and P-channel MOS transistors.

According to an embodiment of the present invention, the first means is a first digital inverter having its output connected to the source terminal of the first switch and the second terminal of the first capacitor is connected to the output of a second digital inverter, the first and second inverters being controlled by the digital block.

### BRIEF DESCRIPTION OF THE DRAWINGS

Features and advantages of the present invention will be discussed in detail in the following non-limiting description of specific embodiments in connection with the accompanying drawings.

FIG. 1, previously described, shows an example of a conventional voltage step-up device;

FIG. 2 schematically shows an embodiment of a device according to an embodiment of the present invention for controlling an analog MOS transistor;

FIG. 3 schematically shows an embodiment of a voltage step-up device according to an embodiment of the present invention comprising the control device of FIG. 2; and

FIG. 4 schematically shows a detail of the devices of FIGS. 2 and 3 according to an embodiment of the invention.

### DETAILED DESCRIPTION

Same reference numerals designate same elements in the different drawings. For clarity, only those elements believed necessary to the understanding of the present invention have been shown.

FIG. 2 shows an embodiment of a device according to the present invention for controlling an N-channel analog MOS transistor 2. The device comprises an inverter 14 formed of digital transistors having its output terminal connected to the source of transistor 2. A first terminal of a capacitor 16 is connected to the gate of transistor 2. The second terminal of capacitor 16 is connected to an output terminal 17 of an inverter 18, substantially identical to inverter 14. A resistor 20 is arranged between the gate of transistor 2 and a node 21 maintained at a biasing voltage Vp by a voltage source 22. Voltage source 22 is such that voltage Vp is greater than threshold voltage Vt of transistor 2, and smaller than the sum of voltage Vt and of supply voltage Vdd of inverters 14 and 18. Inverter 18 is connected at its input to an input terminal IN receiving a digital control signal, so that node 17 receives the logic inverse of the digital control signal. Inverter 14 is connected at its input to logic complement NIN of terminal IN, so that the source of transistor 2 receives the digital control signal. Inverters 14 and 18, the structure of which is not shown, are for example conventional inverters each formed of a P-channel MOS transistor and of an N-channel MOS transistor, the sources of which are respectively connected to voltage Vdd and to ground GND; their connected gates forming the inverter input and their connected drains forming the inverter output.

This circuitry controls transistor 2 on the one hand by adding or subtracting voltage Vdd to bias voltage Vp of the gate of transistor 2 respectively at the rising and falling edges of the digital control signal supplied to terminal IN, and on the other hand by providing the logic inverse of the digital signal to the source of transistor 2.

In a first steady state, where the digital control signal has a logic value “1”, inverters 14 and 18 have their output terminals respectively at voltage Vdd (digital “1”) and at ground voltage GND (digital “0”). Current flows through the resistor 20 to charge the capacitor 16 to voltage Vp such that the gate of transistor 2 is at voltage Vp. The gate-source voltage of transistor 2 is equal to Vp−Vdd, that is, smaller than threshold voltage Vt, and transistor 2 is maintained off.

When the value of the digital control signal switches from “1” to “0”, the output terminals of inverters 14 and 18 are respectively brought to voltages GND and Vdd. Voltage Vp across capacitor 16 adds to voltage Vdd of output terminal 17 of inverter 18, and the gate of transistor 2 is brought to voltage Vp+Vdd. The source of transistor 2 further being at output voltage GND of inverter 14, the gate-source voltage of transistor 2 is then equal to Vp+Vdd. Voltage Vp+Vdd being at least greater by a value Vdd than threshold voltage Vt, transistor 2 is turned on with a low resistance Ron.

This enables turning on transistor 2 with a small resistance Ron even when digital supply voltage Vdd has a value dose to (or even possibly smaller than) threshold voltage Vt of transistor 2.

After switching from a state “1” to “0”, when the digital control signal remains at “0”, the output terminals of inverters 14 and 18 respectively remain at voltages GND and Vdd. Capacitor 16 discharges to a voltage Vp−Vdd, with a time constant which depends on the values of capacitor 16 and of resistor 20. The gate of transistor 2 then falls to voltage Vp. The gate-source voltage of transistor 2 becomes equal to voltage Vp, greater than threshold voltage Vt, and transistor 2 is maintained on.

When the digital control signal switches from “0” to “1”, the output terminals of inverters 14 and 18 are respectively brought to voltages Vdd and GND. Voltage Vp−Vdd across capacitor 16 adds to the zero voltage of output terminal 17 of inverter 18, and the gate of transistor 2 is at voltage Vp−Vdd. The source of transistor 2 further being at output voltage Vdd of inverter 14, the gate-source voltage of transistor 2 is then equal to Vp−2Vdd, that is, smaller than voltage Vt, and transistor 2 is made non-conductive.

When the state is maintained, capacitor 16 charges to voltage Vp with the previous time constant (capacitor 16, resistor 20) to reach the first steady state.

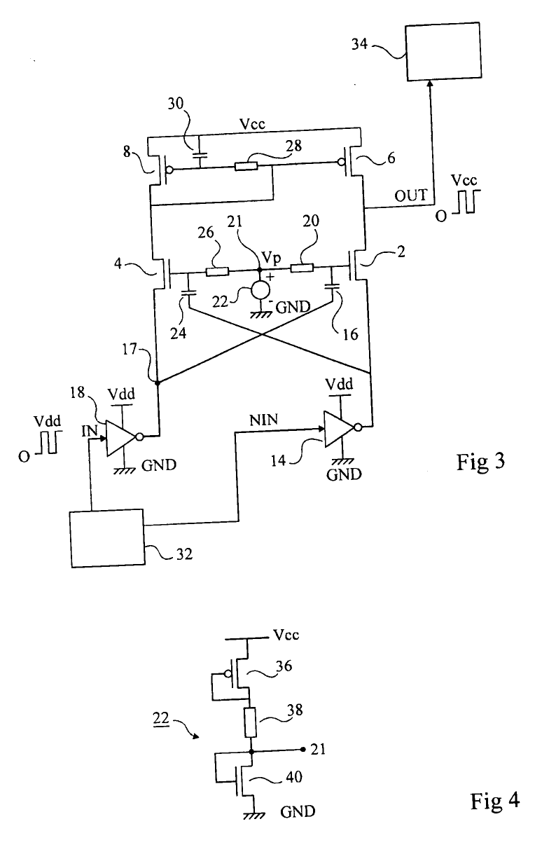

FIG. 3 shows an embodiment of a voltage step-up device according to the present invention using the control device of FIG. 2. The step-up device of FIG. 3 uses the elements of FIG. 2, completing the circuit to have a bistable structure. An N-channel analog MOS transistor 4 substantially identical to transistor 2 has its source connected to output 17 of inverter 18. The gate of transistor 4 is connected via a capacitor 24 to the output of inverter 14, and it is connected via a resistor 26 to node 21. The drain of transistor 4 is connected to the gate of an analog P-channel MOS transistor 6 having its source maintained at a voltage Vcc by an analog voltage source. The drain of transistor 6 is connected to the drain of transistor 2, which forms output terminal OUT of the voltage step-up device. An analog MOS transistor 8 substantially identical to transistor 6 has its drain connected to the drain of transistor 4, and its source connected to voltage Vcc. Voltage Vcc is selected to ensure the saturation of transistors 2 and 6 as well as 4 and 8 in series.

According to an embodiment of the voltage step-up device of the present invention, the gate of transistor 8 is connected to the gate of transistor 6 via a resistor 28, and to the source of transistor 6 via a capacitor 30. A digital block 32 has outputs connected to terminals IN and NIN. An analog block 34 has an input connected to terminal OUT.

Transistors 6 and 8 form a current mirror controlled by transistor 4, in which the control of transistor 8 is received with a predetermined delay depending on resistor 28 and on capacitor 30.

Transistor 4 is controlled in phase opposition with respect to transistor 2. The gate and the source of transistor 4, capacitor 24, and resistor 26 are respectively submitted to the same voltages as those to which are submitted the gate and the source of transistor 2, capacitor 16, and resistor 20 in comparable states and transitions.

Transistor 4 is in a steady on state when the digital control signal is maintained at “1” (transistor 2 then is in a steady off state). The gate of transistor 4 then is at voltage Vp and its source is grounded, the gates of transistors 6 and 8 are substantially grounded and transistors 6 and 8 are on. Terminal OUT then is at voltage Vcc. Preferably, voltage Vp is chosen for resistance Ron of transistor 4 to be strong when its gate-source voltage is Vp, to limit in settable fashion the static consumption of the device according to this embodiment of the present invention.

When transistor 4 is turned off by a switching from “1” to “0” of the digital control signal (that is, when transistor 2 is turned on), the voltage of the gate of transistor 6 is raised to voltage Vcc through transistor 8 which first remains on, which rapidly turns off transistor 6. The gate voltage of transistor 8 rises through transistor 8 with the previous predetermined delay until transistor 8 is off. The turning-on of transistor 2 and the turning-off of transistor 6 bring terminal OUT to voltage GND.

It has been previously seen that transistor 2 is turned on with a small resistance Ron which does not depend on the difference between voltages Vdd and Vt. Similarly, the speed at which transistor 6 is turned off, which depends on the turn-off speed of transistor 4, does not depend on the difference between voltages Vdd and Vt. Thus, the speed at which output terminal OUT of the voltage step-up device is brought from voltage Vcc to voltage GND does not depend on the difference between voltages Vdd and Vt. Further, according to the shown embodiment, the fast turning-off of transistor 6 enables limiting the time for which transistors 2 and 6 are simultaneously on, and thus limiting in settable fashion the power consumption of the voltage step-up device.

Transistor 4 is in a steady off state when the digital control signal is maintained at “0” (transistor 2 then is in a steady on state). Transistors 6 and 8 are then off and terminal OUT is at voltage GND.

By analogy with the turning-on of transistor 2, transistor 4 is turned on with a small resistance Ron by a switching from “0” to “1” of the digital control signal (transistor 2 is then turned off). The gate voltage of transistor 6 is thus rapidly brought to ground through transistor 4, and transistor 6 is rapidly turned on. The gate voltage of transistor 8 is lowered with the previous predetermined delay.

It has been seen previously that the turn-off speed of transistor 2 does not depend on the difference between voltages Vdd and Vt. The speed at which transistor 6 is turned on, which depends on resistance Ron of transistor 4 when it is turned on, thus does not depend on the difference between voltages Vdd and Vt, and the voltage step-up device brings terminal OUT to voltage Vcc at a speed which does not depend on the difference between voltages Vdd and Vt. As a result, the operating speed of the voltage step-up device does not depend on the difference between voltages Vdd and Vt, whereby incidental variations in voltage Vdd do not translate as a phase modulation of the output terminal of the device.

FIG. 4 schematically shows an example of embodiment of voltage source 22 of FIGS. 2 and 3. An analog P-channel MOS transistor 36 has its source connected to voltage Vcc and its gate and its drain connected, via a resistor 38, to an output terminal 21 of the voltage source. An analog N-channel MOS transistor 40 has its drain and its gate connected to terminal 21, and its source connected to ground GND. Preferably, transistors 36 and 40 as well as resistor 38 are selected to generate a voltage Vp slightly greater than threshold voltage Vt of transistors 2 and 4. It should be noted by those skilled in the art that such a structure enables generating an appropriate voltage Vp independently from technological variations. Such a structure also enables rudimentary control of the current supplied at the level of terminal 21 although it is particularly simple.

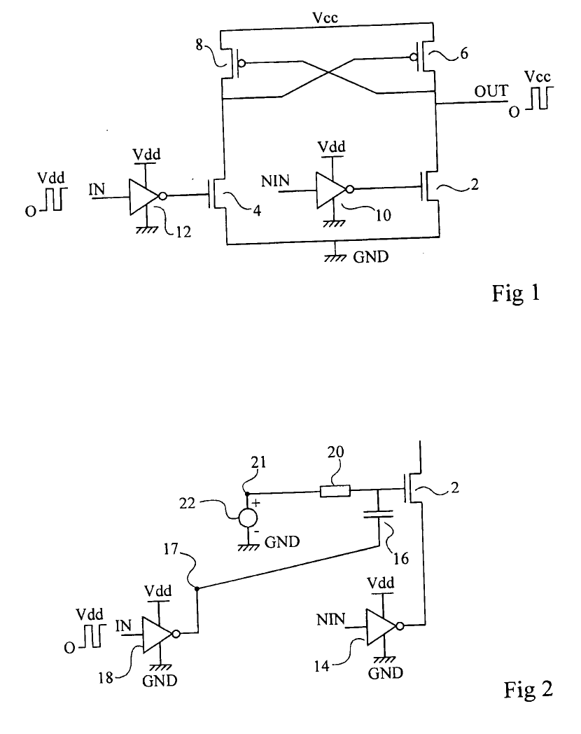

Of course, the present invention is likely to have various alterations, modifications, and improvements which will readily occur to those skilled in the art. In particular, the gate of transistor 8 has been shown as connected to its drain by a resistor and to its source by a capacitor, but it may also be connected as shown in FIG. 1 to the drain of transistor 2.

Similarly, according to an alternative (not shown) of FIG. 4, output terminal OUT connected to the drain of transistor 6 will be replaced with its logic complement NOUT, connected to the drain of transistor 8, if the gate of transistor 8 is directly connected to the drain of transistor 6 and if the gate of transistor 6 is connected to voltage Vcc by capacitor 30 and to the gate of transistor 8 via resistor 28.

The present invention may also apply to negative voltages Vdd and Vcc by inverting the conductivity types of the transistors in appropriate fashion.

Further, the present invention has been described in relation with various elements, but those skilled in the art may readily adapt the present invention to equivalent elements. For example, the analog MOS transistors may be replaced with other power switches having a high threshold voltage such as IGBTs. The inverters connected to the input terminal of the control device and of the voltage step-up device may also be replaced with buffer circuits formed of digital transistors or any other digital control means capable of absorbing a static current.

Such alterations, modifications, and improvements are intended to be part of this disclosure, and are intended to be within the spirit and the scope of the present invention. Accordingly, the foregoing description is by way of example only and is not intended to be limiting.

What is claimed is:

1. A device for controlling a voltage-controlled switch, said switch being provided for connecting a first node to an output of a first means provided for supplying a control digital signal;
second means for biasing the switch control terminal to a level greater than the threshold voltage of the switch and smaller than the sum of said threshold voltage and of the maximum voltage of the digital signal; and
third means for adding or subtracting to said level said maximum voltage of the digital signal respectively at the rising and falling edges of the logic inverse of the digital signal.

2. The control device of claim 1, wherein:
said second means comprise a first resistor arranged between the control terminal of the switch and a voltage source; and
said third means comprise a first capacitor having a first terminal connected to the control terminal of the switch and having its second terminal receiving the logic inverse of the digital signal.

3. A voltage step-up device comprising:
a first switch having its voltage controlled by the device of claim 2, said first node forming the output terminal of the voltage step-up device;
a second switch substantially identical to the first switch, said second switch being provided for connecting a second node to the second terminal of the first capacitor, the control terminal of the second switch being connected to the output of the first means via a second capacitor and connected to the voltage source via a second resistor; and
fourth means capable of bringing the output terminal of the device to a predetermined high voltage, greater than said maximum voltage of the digital signal, when the first switch is non-conductive.

4. The voltage step-up device of claim 3, wherein said fourth means comprise:
a high voltage source;
a third voltage-controlled switch provided for connecting the high voltage source to said first node, the control terminal of the third switch being connected to the second node; and
a fourth switch substantially identical to the third switch, provided for connecting the high voltage source to said second node, the control terminal of the fourth switch being connected to the control terminal of the third switch via a third resistor and to the high voltage source via a third capacitor.

5. The voltage step-up device of claim 3, wherein the fourth means comprises:
a high voltage source;
a third voltage-controlled switch provided for connecting the high voltage source to the first node, the control terminal of the third switch being connected to the second node; and
a fourth switch identical to the third switch, provided for connecting the high voltage source to the second node, the control terminal of the fourth switch being connected to the first node.

6. An integrated circuit comprising a digital block capable of providing a control signal to an analog block via the voltage step-up device of claim 3, wherein the maximum voltage of the digital signal is equal to the supply voltage of the digital block and wherein the high voltage is equal to the supply voltage of the analog block.

7. The integrated circuit of claim 6, wherein the first and third switches respectively are N- and P-channel MOS transistors.

8. The integrated circuit of claim 7, wherein said first means comprise a first digital inverter having its output connected to the source terminal of the first switch and wherein the second terminal of the first capacitor is connected to the output of a second digital inverter, the first and second inverters being controlled by the digital block.

9. A control-signal generator, comprising:
a first boost circuit having a first node operable to receive a boost voltage and having a second node operable to receive an input signal; and
a first switch having a control node coupled to the first node of the boost circuit, a first drive node operable to receive the input signal, and a second drive node, the transistor operable to generate a control signal on the second drive node in response to the boost voltage and the input signal.

10. The control-signal generator of claim 9 wherein the first switch comprises a transistor.

11. The control-signal generator of claim 9 wherein the boost circuit comprises a capacitor.

12. The control-signal generator of claim 9 wherein:
the first switch is operable to dose when a voltage between the control node and the first drive node is equal to or greater than a threshold voltage;
the input signal has a level that ranges from a logic-low voltage to a logic-high voltage; and
the boost voltage is greater than the threshold voltage and less than a sum of the threshold voltage and the logic-high voltage.

13. The control-signal generator of claim 9, further comprising:
a second boost circuit having a first node operable to receive the boost voltage and having a second node operable to receive the input signal;
a second switch having a control node coupled to the first node of the second boost circuit, a first drive node operable to receive the input signal, and a second drive node, the second transistor operable to generate a complement of the control signal on the second drive node in response to the boost voltage and the input signal; and
a current mirror having an input node coupled to the second drive node of the second switch and having an output node coupled to the second drive node of the first switch.

14. The control-signal generator of claim 9, further comprising:
a second boost circuit having a first node operable to receive the boost voltage and having a second node operable to receive the input signal;
a second switch having a control node coupled to the first node of the second boost circuit, a first drive node operable to receive the input signal, and a second drive node, the second switch operable to generate a complement of the control signal on the second drive node in response to the boost voltage and the input signal;
a third switch having a control node and a first drive node coupled to the second drive node of the second switch, and having a second drive node operable to receive a supply voltage; and
a fourth switch having a control node coupled to the second drive node of the second switch, a first drive node coupled to the second drive node of the first switch, and a second drive node operable to receive the supply voltage.

15. The control-signal generator of claim 9, further comprising:
wherein the first transistor comprises a first NMOS transistor,
a second boost circuit having a first node operable to receive the boost voltage and having a second node operable to receive the input signal;
a second NMOS transistor having a control node coupled to the first node of the second boost circuit, a first drive node operable to receive the input signal, and a second drive node, the second NMOS transistor operable to generate a complement of the control signal on the second drive node in response to the boost voltage and the input signal;
a first PMOS transistor having a control node and a first drive node coupled to the second drive node of the second NMOS transistor, and having a second drive node operable to receive a supply voltage; and
a second PMOS transistor having a control node coupled to the second drive node of the second NMOS transistor, a first drive node coupled to the second drive node of the first NMOS transistor, and a second drive node operable to receive the supply voltage.

16. The control-signal generator of claim 9, further comprising:
a second boost circuit having a first node operable to receive the boost voltage and having a second node operable to receive the input signal;
a second switch having a control node coupled to the first node of the second boost circuit, a first drive node operable to receive the input signal, and a second drive node, the second switch operable to generate a complement of the control signal on the second drive node in response to the boost voltage and the input signal;
an impedance having a first node coupled to the second drive node of the second switch and having a second node;
a third switch having a control node coupled to the second node of the impedance, a first drive node coupled to the second drive node of the second switch, and a second drive node operable to receive a supply voltage;
a fourth switch having a control node coupled to the second drive node of the second switch, a first drive node coupled to the second drive node of the first switch, and a second drive node operable to receive the supply voltage; and
a capacitor having a first node coupled to the control node of the third switch and having a second node operable to receive the supply voltage.

17. The control-signal generator of claim 9, further comprising:
a second boost circuit having a first node operable to receive the boost voltage and having a second node operable to receive the input signal;
a second switch having a control node coupled to the first node of the second boost circuit, a first drive node operable to receive a complement of the input signal, and a second drive node, the second switch operable to generate a complement of the control signal on the second drive node in response to the boost voltage and the input signal; and
a current mirror having an input node coupled to the second drive node of the second switch and having an output node coupled to the second drive node of the first switch.

18. An integrated circuit, comprising:
a boost circuit having a first node operable to receive a boost voltage and having a second node operable to receive an input signal; and
a switch having a control node coupled to the first node of the boost circuit, a first drive node operable to receive the input signal, and a second drive node, the switch operable to generate a control signal on the second drive node in response to the boost voltage and the input signal.

19. The integrated circuit of claim 16 wherein:
the input signal comprises a first logic signal;
the second node of the boost circuit is operable to receive a complement of the first logic signal; and
the control signal comprises a second logic signal that is in phase with the input first logic signal.

20. A method, comprising:
applying a sum of a boost voltage and a logic voltage to a control terminal of a switch;
applying a complement of the logic voltage to a first drive node of the switch; and
generating a control voltage representing a first logic level on a second drive node of the switch in response to the sum of the boost and logic voltages and the complement of the logic voltage.

21. The method of claim 20 wherein the complement of the logic voltage represents the first logic level.

22. The method of claim 20, further comprising:
applying the complement of the logic voltage to the control terminal of the switch;
applying the logic voltage to the first drive node of the switch; and
generating the control voltage representing a second logic level on the second drive node of the switch in response to the complement of the logic voltage and the logic voltage.

23. The method of claim 21 wherein the logic voltage represents the second logic level.

24. The method of claim 20, further comprising:
applying the complement of the logic voltage to the control terminal of the switch;
charging to the boost voltage a capacitor that is coupled to the control terminal of the switch;
applying the logic voltage to the first drive node of the switch; and
generating the control voltage representing a second logic level on the second drive node of the switch in response to the complement of the logic voltage and the logic voltage.

25. The method of claim 20 wherein the boost voltage is greater than a threshold voltage of the switch and less than a sum of the threshold voltage and the logic voltage.
